(19) United States
(12) Patent Application Publication
(10) Pub. No.: US 2025/0218984 A1
(43) Pub. Date: Jul. 3, 2025

(54) ENCAPSULATION TECHNIQUES FOR COMPONENTS EMBEDDED IN A CORE LAYER OF A PACKAGE SUBSTRATE

(71) Applicant: Intel Corporation, Santa Clara, CA (US)

(72) Inventors: Zhixin Xie, Chandler, AZ (US); Andrew Matthew Jimenez, Mesa, AZ (US); Liang He, Chandler, AZ (US); Jung Kyu Han, Chandler, AZ (US); Gang Duan, Chandler, AZ (US)

(73) Assignee: Intel Corporation, Santa Clara, CA (US)

(21) Appl. No.: 18/397,962

(22) Filed: Dec. 27, 2023

(51) Int. Cl. H01L 23/64; H01L 21/48; H01L 23/498

(52) U.S. Cl. CPC H01L 23/645; H01L 21/4857; H01L 23/49822; H01L 23/49838; H01L 23/49861; H01L 23/49894

(57) ABSTRACT

In embodiments herein, a circuit component (e.g., a deep trench capacitor) is embedded within a core layer of a substrate. The circuit component may be encapsulated by multiple (e.g., two) layers of dielectrics or by a polymer material.

### BACKGROUND

As integrated circuit chip technology continues to scale downward, average and transient currents can exponentially rise. The increased currents demand more stable power delivery to the chips, especially for high performance computing applications. Decoupling capacitors can be used to reduce the impedance of a power distribution system, to reduce the power supply noise. Metal-insulator-metal (MIM) decoupling capacitors have been demonstrated to have good power integrity performance. However, as switching frequency and circuit power increases at the same time as operation voltage and noise margin decrease, higher performance decoupling capacitors may be required to mitigate potential voltage droop and noise issues. Deep trench capacitors (DTC) may be one option for mitigating these or other power delivery challenges.

### BRIEF DESCRIPTION OF THE DRAWINGS

FIG. 1 illustrates an example package substrate with an embedded component in a core layer of the package substrate.

FIG. 2 illustrates an example multi-die integrated circuit package with an embedded component in a core layer of the package substrate.

FIGS. 3A-3B illustrate an example process for encapsulating a circuit component in an integrated circuit package substrate in accordance with embodiments of the present disclosure.

FIGS. 4A-4B illustrate another example process for encapsulating a circuit component in an integrated circuit package substrate in accordance with embodiments of the present disclosure.

FIGS. 5A-5B illustrate example systems that may incorporate the architectures described herein.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

Embodiments of the present disclosure relate to techniques for embedding circuit components, such as capacitors or inductors inside a package substrate. For instance, certain embodiments may embed deep trench capacitors (DTCs) in an integrated circuit package substrate, e.g., inside a core layer, so that it is close to an integrated circuit compute die to optimize working performance. DTCs may be three dimensional (3D) vertical capacitors formed by etching a deep trench (DT) into a silicon substrate. Currently, the thickness of DTCs is limited to approximately 600-700 um due to the fabrication process used. In contrast, the core layer of a package substrate can have a thickness of up to 1400 μm or more, creating a significant difference between the thicknesses of the DTC and the core layer, which can lead to cavity filling difficulties and can potentially impact assembly yields (e.g., due to issues caused by the contacts of the embedded circuit component not being properly aligned with other electrical contacts of the substrate).

For instance, after a DTC has been embedded, a layer of dielectrics may be used to fill the cavity, encapsulating and insulating the component. The dielectric layer used may include an epoxy mold compound with fillers, buildup dielectrics (e.g., ABF), polyimide, or other types of organic dielectric materials. Using a single layer build-up dielectric or epoxy mold compound for encapsulation of the component can present difficulties though. For instance, one difficulty lies in balancing of the viscosity and the coefficient of thermal expansion (CTE) of the chosen material. Generally, for epoxy-based organic dielectric layers, the greater the filler loading in the material, the higher the viscosity. It can thus become difficult to laminate and plug a high viscosity material into the cavity around the component, with a typical failure mode being voiding in the encapsulation (that is, voids inside the cavity around a component). Conversely, when the filler loading is lower in the material used, the viscosity is also lower and the CTE is higher. However, a lower viscosity material can also cause component shifting and a higher CTE can lead to panel warpage after the encapsulation.

Thus, embodiments of the present disclosure provide techniques that can solve these or other issues in the encapsulation process. In some embodiments, for example, a non-conductive polymer material can be deposited before the dielectric encapsulation step. This can provide a cost-effective way to increase quality/yield, while also being flexible with regard to material choices. As another example, in some embodiments, a double layer of dielectrics, with each layer have different material characteristics (e.g., filler type, filler loading, resin type, etc.), can be used instead of a single dielectric layer. This can provide increased choice with regard to the dielectric layer choices and can increase process yields while also lowering manufacturing costs. Moreover, either technique can help to prevent or control warpage during processing steps after the encapsulation has been performed.

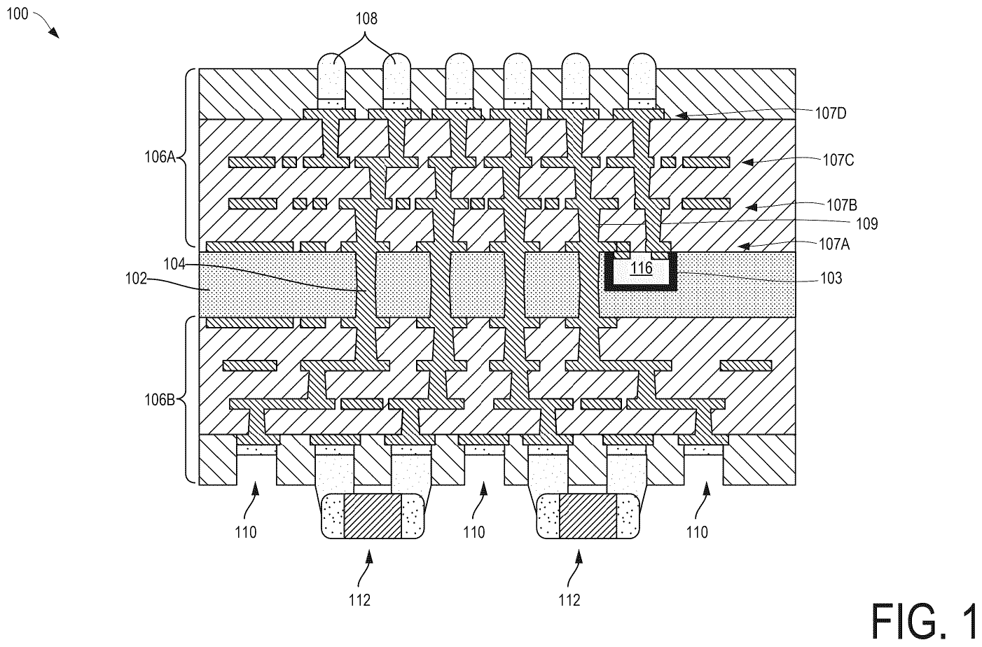

FIG. 1 illustrates an example package substrate 100 with an embedded component in a core layer 102 of the package substrate. In particular, the example package substrate 100 includes a core layer 102 with buildup layers 106 formed on either side of the core layer 102, i.e., with buildup layers 106A on the top side of the core layer 102 and buildup layers 106B on the bottom side of the core layer 102. The core layer 102 may be formed from an organic material (e.g., a material comprising Carbon, such as comprising Silicon and Carbon), a composite material (e.g., a copper clad laminate (CCL) material), or may be formed of glass or a glass-based material (e.g., comprising Silicon (e.g., at least 26% by weight) and Oxygen (e.g., at least 26% by weight)). A glass core may also have one or more additive elements (e.g., as least 5% by weight) such as Aluminum, Boron, Magnesium, Calcium, Barium, Tin, Sodium, Potassium, Strontium, Phosphorus, Zirconium, Lithium, Titanium, and Zinc. Examples of glass core materials may include aluminosilicate, borosilicate, alumino-borosilicate, silica, or fused silica, and the materials may further include one or more additives, such as Al₂O₃, B₂O₃, MgO, CaO, SrO, BaO, SnO₂, Na₂O, K₂O, SrO, P₂O₃, ZrO₂, Li₂O, Ti, and Zn.

The buildup layers 106 include metal traces in metallization layers (e.g., 107A-D) and pillars (e.g., 109) between the metallization layers to electrically couple the solder bumps 108 at the top of the package substrate 100 with the pads 110 at the bottom of the substrate. In certain instances, for example, an integrated circuit die may be coupled to a top side of the package substrate 100 and connect to the solder bumps 108, and the package substrate 100 may be coupled to a circuit board (e.g., a motherboard, main board, etc.) via the pads 110 at the bottom of the package substrate 100. The package substrate 100 also includes land side capacitors 112 coupled on a bottom side of the package substrate 100.

In addition, the package substrate 100 includes a circuit component 116 that is embedded within the core layer 102, i.e., within a cavity 103 (which may also be referred to as an opening in the core layer 102). The component 116 may be encapsulated by a mold material inside the cavity 103 in the core layer 102. In certain embodiments, the circuit component 116 may be a passive circuit component, such as a capacitor (e.g., a deep trench capacitor) or inductor. Although one component 116 is embedded within the core layer 102 in the example shown, multiple circuit components may be embedded within the core layer 102 in other embodiments. For example, multiple components 116 may be embedded in the same cavity or opening in the core layer 102, multiple components 116 may be embedded in different respective cavities/openings in the core layer, or a combination thereof.

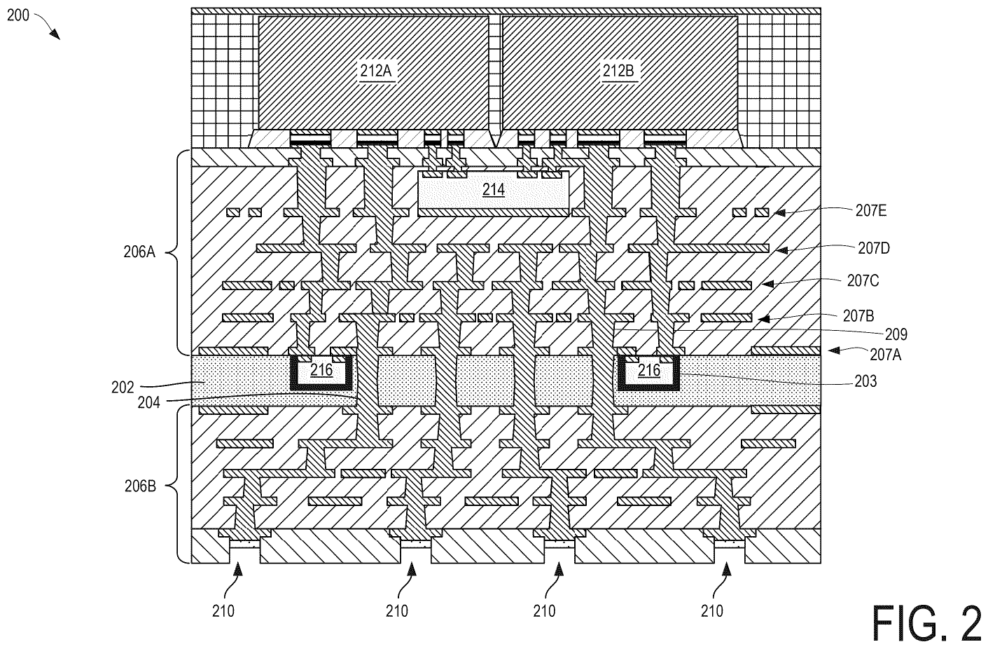

FIG. 2 illustrates an example multi-die integrated circuit package 200 with an embedded component 216 in a core layer 202 of the package substrate. The package 200 includes a core layer 202 and vias 204 through the core layer 202. Buildup layers 206 are formed on the top and bottom sides of the core layer 202, with buildup layers 206A on the top side of the core layer 202 and the buildup layers 206B on bottom side of the core layer 202. The core layer 202 may be formed from a organic material (e.g., a material comprising Carbon, such as comprising Silicon and Carbon), a composite material (e.g., a copper clad laminate (CCL) material), or may be formed of glass or a glass-based material (e.g., comprising Silicon (e.g., at least 26% by weight) and Oxygen (e.g., at least 26% by weight)). A glass core may also have one or more additive elements (e.g., as least 5% by weight) such as Aluminum, Boron, Magnesium, Calcium, Barium, Tin, Sodium, Potassium, Strontium, Phosphorus, Zirconium, Lithium, Titanium, and Zinc. Examples of glass core materials may include aluminosilicate, borosilicate, alumino-borosilicate, silica, or fused silica, and the materials may further include one or more additives, such as Al₂O₃, B₂O₃, MgO, CaO, SrO, BaO, SnO₂, Na₂O, K₂O, SrO, P₂O₃, ZrO₂, Li₂O, Ti, and Zn.

The buildup layers 206 include metal traces in metallization layers (e.g., 207A-E) and pillars (e.g., 209) between the metallization layers as shown to electrically couple components on the top of the package 200 with the pads 210 at the bottom of the package. For example, the layers 206 may provide connections between the integrated circuit (IC) dies 212 coupled to the top side of the package to a circuit board (e.g., a motherboard, main board, etc.) via the pads 210 at the bottom of the package. The package 200 also includes a bridge circuitry component 214 located in the buildup layers 206A that electrically couples the first IC die 212A with the second IC die 212B. The bridge circuitry component 214 may include passive and/or active components to interconnect the IC dies 212. The bridge circuitry component 214 may be an Intel® embedded multi-die interconnect bridge (EMIB) in certain embodiments.

In addition, the package 200 includes two circuit components 216 that are embedded within the core layer 202, i.e., within a cavity 203 (which may be referred to as an opening in the core layer 202). Each component 216 may be encapsulated by a mold material inside the cavity 203. Like the component 116 of FIG. 1, the circuit components 216 may be a passive circuit component, such as a capacitor (e.g., a deep trench capacitor) or inductor, in certain embodiments. Although two components 216 are embedded within the core layer 202 in the example shown, any number of circuit components may be embedded within the core layer 102 in other embodiments. For example, multiple components 216 may be embedded in the same cavity or opening in the core layer 202, multiple components 216 may be embedded in different respective cavities/openings in the core layer, or a combination thereof.

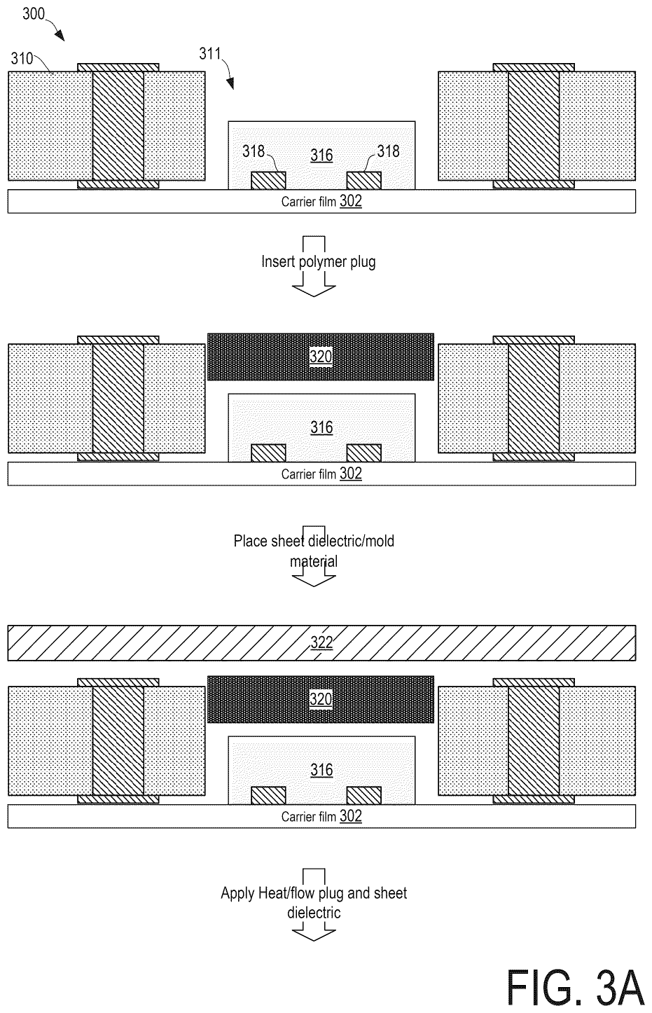

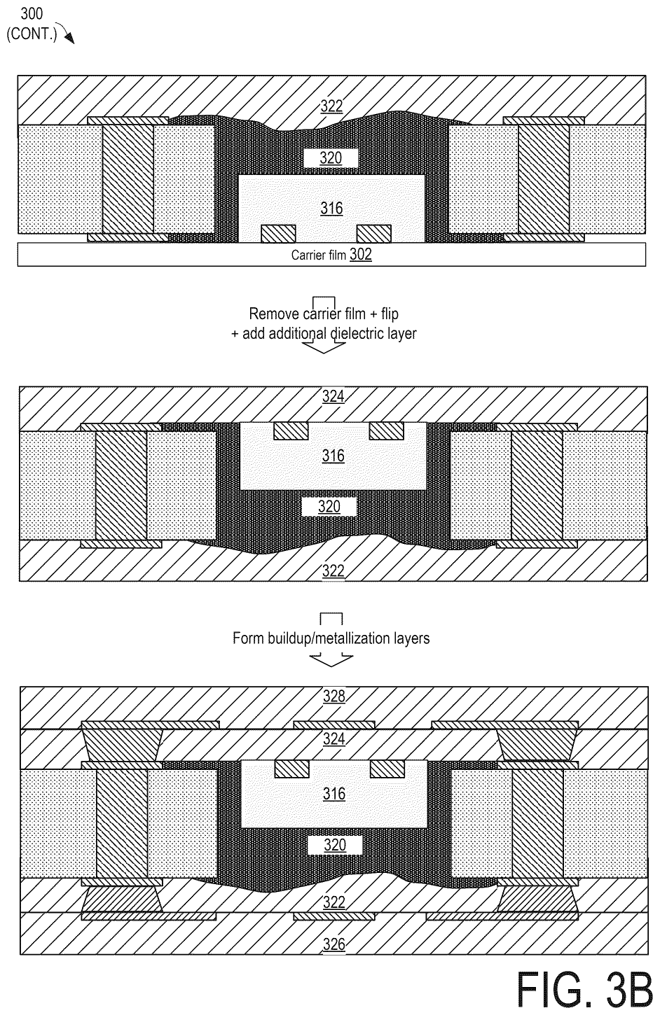

FIGS. 3A-3B illustrate an example process 300 for encapsulating a circuit component 316 in an integrated circuit package substrate in accordance with embodiments of the present disclosure. The process may include additional, fewer, or different operations than those shown or described below. For example, certain operations may be performed in a slightly different order than shown or may be performed simultaneously (when shown as separate steps). In some embodiments, one or more of the operations shown include multiple operations, sub-operations, etc. Further, the example components shown might not be to scale with respect to each other, and the core layer may be larger (e.g., in the x- and y-directions, with more vias, pads, or other components) than the portion shown.

As shown in FIG. 3A, a component 316 is placed into a cavity 311 within a core layer 310 of a substrate. The component 316 may be a deep trench capacitor in some embodiments, or may be another type of circuit component. The component 316 is placed into the cavity 311 using a temporary adhesive carrier film 302 as shown. Then, a non-conductive polymer material 320 can be placed into the cavity 311 to encapsulate the component 316. In some embodiments, the polymer material 320 may be in liquid form, including having a paste-like consistency, and may be dispensed into the cavity 311, e.g., by stencil-based screen printing, inkjet printing, pneumatic plunger dot dispensing, or another suitable type of printing/injection technique. The polymer material 320 could include epoxy, polyimide, polyacrylate (and their composites), prepreg, or other organic dielectric materials or composites. In some embodiments, the polymer material 320 includes filler elements dispersed in the material 320. The filler elements can include, for example, one or more of silicates, quartz, mica, silicate, titanium dioxide, amorphous silicas, magnesium carbonate, aluminum nitride, alumina, boron nitride, magnesium hydroxide, chalk, limestone, feldspar, barium sulfate, or cobalt iron alloy.

Then a buildup dielectric layer 322 can be laminated onto the core layer as shown. The layer 322 and polymer material 320 can then be cured together. In some embodiments, however, the polymer material 320 may be cured prior to the lamination and curing of the layer 322. In some embodiments, the interface between the polymer material 320 and the dielectric layer 322 may be irregular, e.g., as shown in FIG. 3B, and in some instances, may be interdigitated between the two materials. In some embodiments, the dielectric layer 322 may include filler materials, and one or more of the following characteristics can be different between the polymer material layer 320 and the build-up dielectric material layer 322: filler size (which can be in the nanometer-micrometer range, filler loading percentage or density, filler type, filler shape (e.g., particulate, fiber, or both), filler hollow ratio, or polymer resin type.

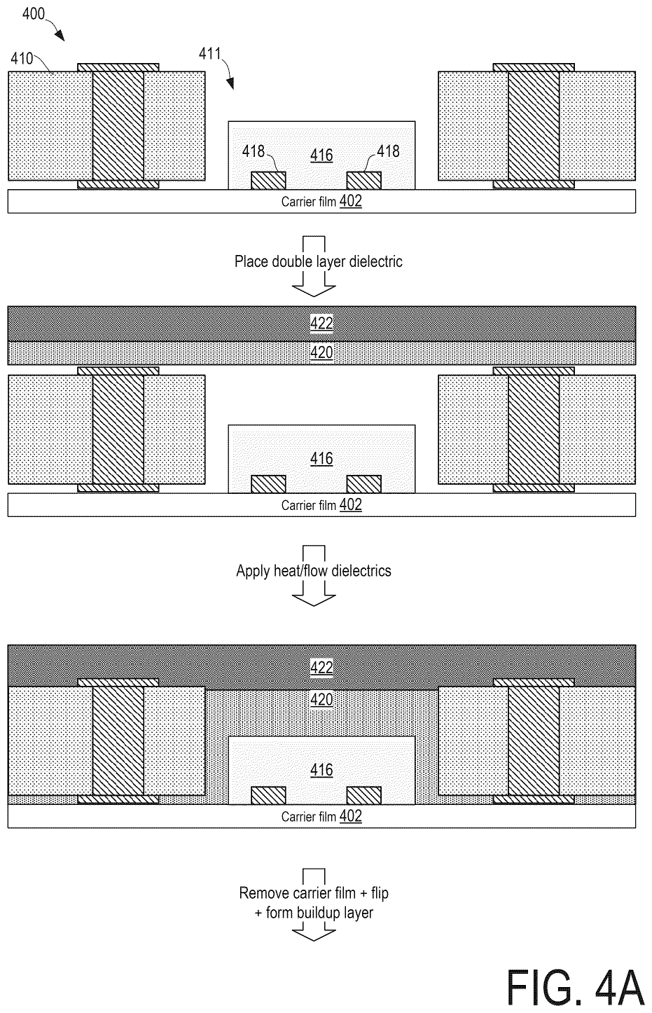

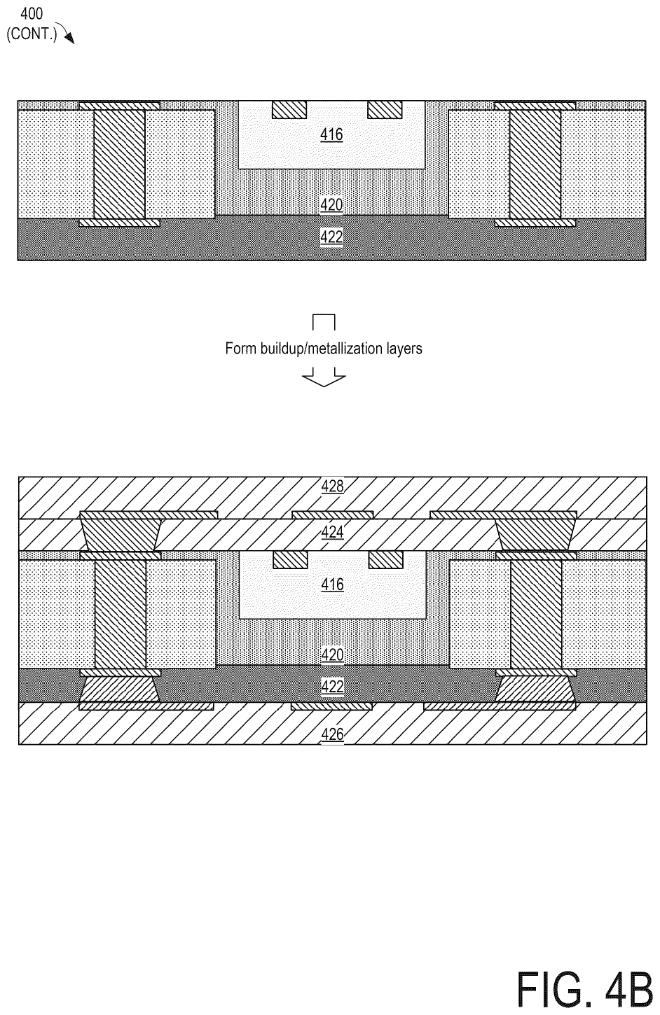

FIGS. 4A-4B illustrate another example process for encapsulating a circuit component in an integrated circuit package substrate in accordance with embodiments of the present disclosure. The process may include additional, fewer, or different operations than those shown or described below. For example, certain operations may be performed in a slightly different order than shown or may be performed simultaneously (when shown as separate steps). In some embodiments, one or more of the operations shown include multiple operations, sub-operations, etc. Further, the example components shown might not be to scale with respect to each other, and the core layer may be larger (e.g., in the x- and y-directions, with more vias, pads, or other components) than the portion shown.

As shown in FIG. 4A, the component 416 is first placed into a cavity 411 in a core layer 410 of a substrate. The component 416 may be a deep trench capacitor in some embodiments, or may be another type of circuit component. The component 416 is placed into the cavity 411 using a temporary adhesive carrier film 402 as shown. Then, a double layer dielectric is laminated or otherwise placed onto or above the panel comprising the core layer 410. As shown, the double layer dielectric may include two dielectric layers 420, 422, each with different material characteristics (e.g., different CTE, viscosity when flowing, Young's modulus, etc.). For example, the layer 420 may be a dielectric material with higher viscosity and lower CTE (e.g., for better flowing into the cavity to encapsulate the component 416), while the layer 420 may be a dielectric material with lower viscosity and higher CTE (e.g., for better CTE matching with the buildup layers that will later be formed on the substrate). In some embodiments, the dielectric layers 420, 422 may each include one or more filler materials, such as, for example, silicates, quartz, mica, silicate, titanium dioxide, amorphous silicas, magnesium carbonate, aluminum nitride, alumina, boron nitride, magnesium hydroxide, chalk, limestone, feldspar, barium sulfate, or cobalt iron alloy. The fillers can have sizes in the nanometer to micrometer range, in certain embodiments. The dielectric layers 420, 422 may differ in one or more of the following ways: filler size, filler loading percentage or density, filler material type, filler shape (e.g., particulate, fiber, or both), filler hollow ratio, or polymer resin type.

Then, the double layer dielectric material is heated and pressed, e.g., by a compression molding tool, vacuum lamination tool, hot press, or other suitable tool, to allow the melted dielectric resin to flow into the cavity 411. Once the cavity has been filled and the component encapsulated, the flowed dielectric materials are cured. The temporary carrier film 402 can then be removed. In some embodiments, the core layer and/or the encapsulating dielectric layer can be ground to flatten the surface(s). The panel can be flipped as shown, and a semi-additive process can be performed to form buildup layers on either side of the core layer, e.g., to form redistribution layers (RDLs) or pattern with solder interconnects.

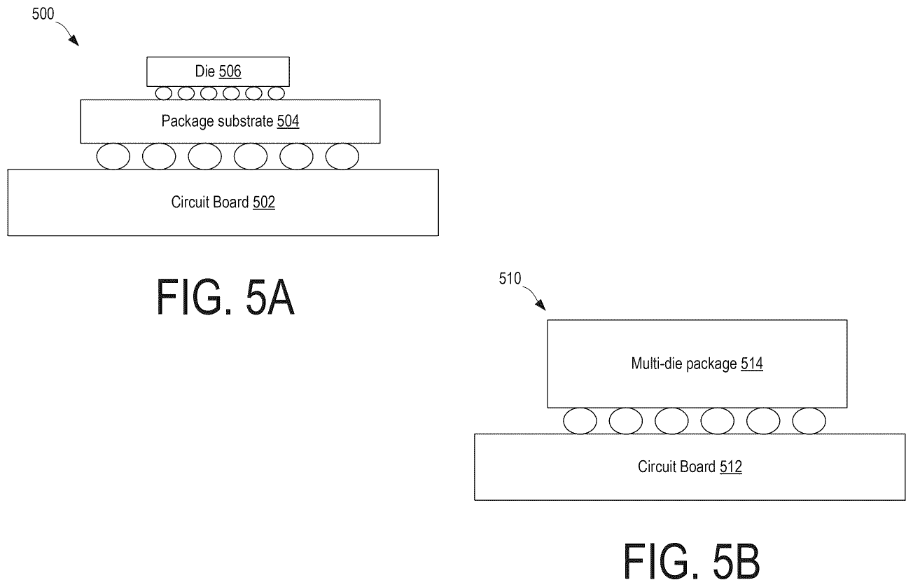

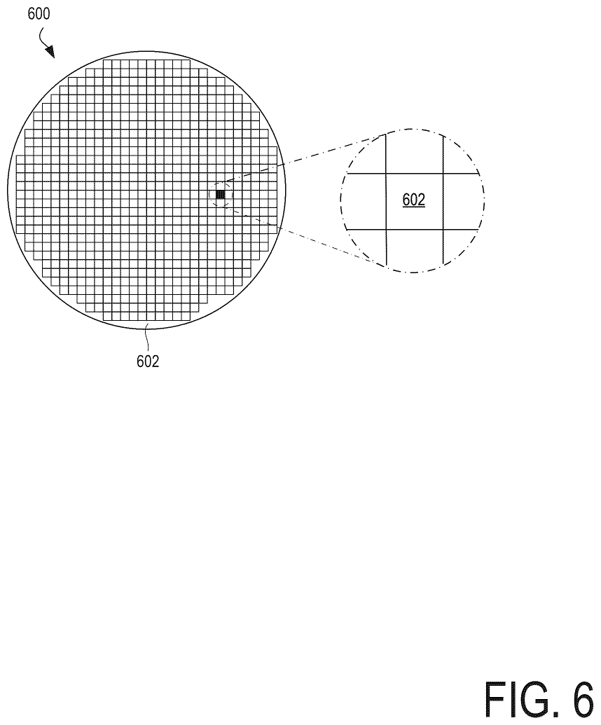

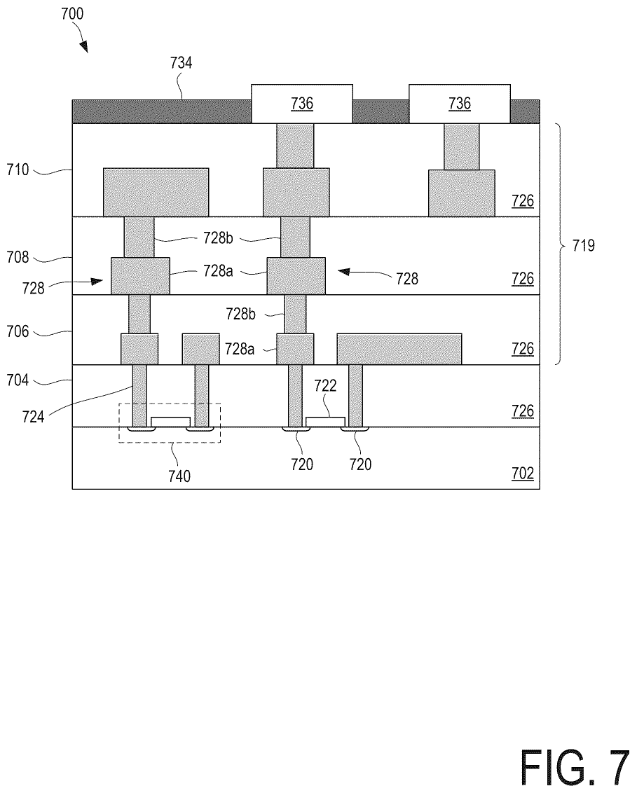

FIGS. 5A-5B illustrate example systems 500, 510 that may incorporate the architectures described herein. The example system 500 of FIG. 5A includes a circuit board 502, which may be implemented as a motherboard or main board of a computer system in some embodiments. The example system 500 also includes a package substrate 504 with an integrated circuit die 506 attached to the package substrate 504. The die 506 may be a packaged or unpacked integrated circuit product that includes one or more integrated circuit dies (e.g., the die 602 of FIG. 6, the integrated circuit device 700 of FIG. 7) and/or one or more other suitable components. The die 506 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 506 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 506 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 504 may provide electrical connections between the die 506 and the circuit board 502.

Similar to the system 500, the system 510 also includes a circuit board 512, which may be implemented as a motherboard or main board of a computer system in some embodiments. The system 510 also includes a multi-die package 514, which includes multiple integrated circuits/dies (e.g., 506), and interconnections between the dies in one or more metallization layers. The multi-die package 514 may include, for example, one or more silicon interposers, one or more silicon bridges embedded in the package substrate (e.g., an Intel® embedded multi-die interconnect bridge (EMIB)), or combinations thereof.

The main circuit boards 502, 512 may provide electrical connections to other components of a computer system, e.g., memory, storage, network interfaces, peripheral devices, power supplies, etc. The main circuit board may include one or more traces and circuit components to provide interconnects between such computer system components.

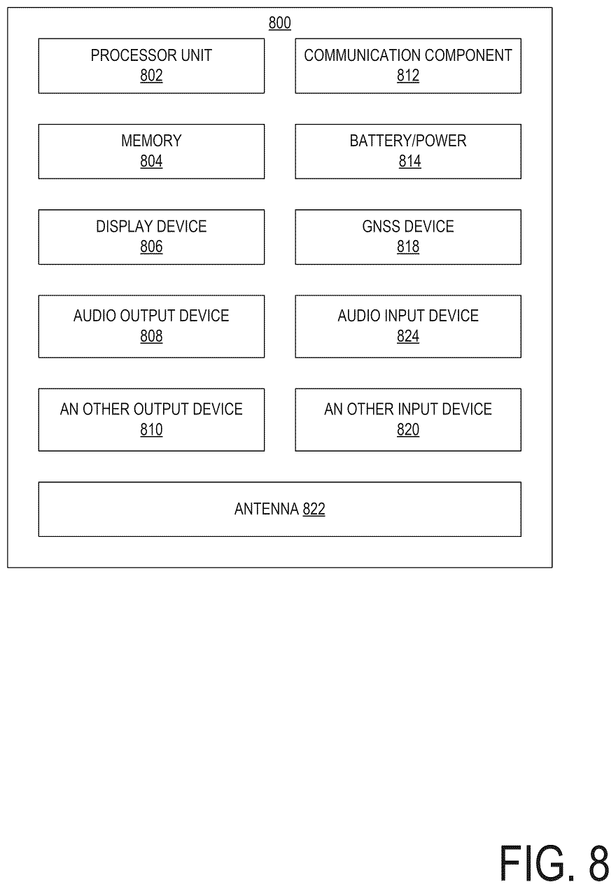

FIG. 6 is a top view of a wafer 600 and dies 602 that may incorporate any of the embodiments disclosed herein. The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 802 of FIG. 8) or other logic that is configured to store information in the memory devices or execute instructions stored in the memory array.

FIG. 7 is a cross-sectional side view of an integrated circuit device 700 that may be included in any of the embodiments disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs) or ferroelectric field-effect transistors (FeFETs), e.g., those described herein) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 7, the example transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the dic substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 8 is a block diagram of an example electrical device 800 that may include one or more of the embodiments disclosed herein. For example, any suitable ones of the components of the electrical device 800 may include one or more of the integrated circuit devices 700 or integrated circuit dies 602 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include an other output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit package substrate comprising: a core layer defining a cavity; a circuit component inside the cavity; a first dielectric layer inside the cavity, the first dielectric layer adjacent the circuit component; a second dielectric layer inside the cavity and below the first dielectric layer; and buildup layers on the core layer, the buildup layers comprising a plurality of metallization layers, wherein at least one metallization layer is in connection with the circuit component.

Example 2 includes the subject matter of Example 1, wherein the first dielectric layer encapsulates the circuit component in the cavity.

Example 3 includes the subject matter of Example 1 or 2, wherein the first dielectric layer comprises first filler materials and the second dielectric layer comprises second filler materials.

Example 4 includes the subject matter of Example 3, wherein the first filler materials are different from the second filler materials.

Example 5 includes the subject matter of Example 3 or 4, wherein a density of the first filler materials in the first dielectric layer is different than a density of the second filler materials in the second dielectric layer.

Example 6 includes the subject matter of any one of Examples 3-5, wherein the first filler materials have a different size than the second filler materials.

Example 7 includes the subject matter of any one of Examples 3-6, wherein the first filler materials and the second filler materials comprise one or more of silicate, amorphous silicas, quartz, mica, titanium dioxide, magnesium carbonate, aluminum nitride, alumina, boron nitride, magnesium hydroxide, chalk, limestone, feldspar, barium sulfate, and cobalt iron alloy.

Example 8 includes the subject matter of any one of Examples 1-7, wherein the first dielectric layer has a higher coefficient of thermal expansion (CTE) than the second dielectric layer.

Example 9 includes the subject matter of any one of Examples 1-8, wherein the core layer comprises an organic material.

Example 10 includes the subject matter of any one of Examples 1-8, wherein the core layer comprises glass.

Example 11 includes the subject matter of any one of Examples 1-10, wherein the circuit component is a capacitor or inductor.

Example 12 includes the subject matter of Example 11, wherein the circuit component is a deep trench capacitor.

Example 13 is an integrated circuit package substrate comprising: a core layer defining a cavity; a circuit component at least partially inside the cavity; a polymer material inside the cavity adjacent the circuit component; and buildup layers on the core layer, the buildup layers comprising a plurality of metallization layers, wherein at least one metallization layer is in connection with the circuit component.

Example 14 includes the subject matter of Example 13, wherein the polymer material encapsulates the circuit component in the cavity.

Example 15 includes the subject matter of Example 13 or 14, wherein the polymer material comprises one or more of an epoxy, a polyimide, a polyacrylate or polyacrylate composites, and a prepreg material.

Example 16 includes the subject matter of any one of Examples 13-15, wherein the polymer material comprises a filler material.

Example 17 includes the subject matter of Example 16, wherein the filler material comprises one or more of silicate, amorphous silicas, quartz, mica, titanium dioxide, magnesium carbonate, aluminum nitride, alumina, boron nitride, magnesium hydroxide, chalk, limestone, feldspar, barium sulfate, and cobalt iron alloy.

Example 18 includes the subject matter of any one of Examples 13-17, wherein the core layer comprises an organic material.

Example 19 includes the subject matter of any one of Examples 13-17, wherein the core layer comprises glass.

Example 20 includes the subject matter of any one of Examples 13-19, wherein the circuit component is a capacitor or inductor.

Example 21 includes the subject matter of Example 20, wherein the circuit component is a deep trench capacitor.

Example 22 is an integrated circuit package substrate comprising: a core layer; first buildup layers on a first side of the core layer, the first buildup layers comprising a plurality of metallization layers; second buildup layers on a second side of the core layer, the second buildup layers comprising a plurality of metallization layers; a circuit component in an opening in the core layer between the first buildup layers and the second buildup layers; a first dielectric layer and a second dielectric layer in the opening in the core layer between the first buildup layers and the second buildup layers, the first dielectric layer adjacent the circuit component.

Example 23 includes the subject matter of Example 22, wherein the first dielectric layer is a polymer material.

Example 24 includes the subject matter of Example 22 or 23, wherein the first dielectric layer encapsulates the circuit component in the opening.

Example 25 includes the subject matter of any one of Examples 22-24, wherein the first dielectric layer comprises first filler materials and the second dielectric layer comprises second filler materials.

Example 26 includes the subject matter of Example 25, wherein the first filler materials are different from the second filler materials.

Example 27 includes the subject matter of Example 25 or 26, wherein a density of the first filler materials in the first dielectric layer is different than a density of the second filler materials in the second dielectric layer.

Example 28 includes the subject matter of any one of Examples 25-27, wherein the first filler materials have a different size than the second filler materials.

Example 29 includes the subject matter of any one of Examples 25-28, wherein the first filler materials and the second filler materials comprise one or more of silicate, amorphous silicas, quartz, mica, titanium dioxide, magnesium carbonate, aluminum nitride, alumina, boron nitride, magnesium hydroxide, chalk, limestone, feldspar, barium sulfate, and cobalt iron alloy.

Example 30 includes the subject matter of any one of Examples 22-29, wherein the first dielectric layer has a higher coefficient of thermal expansion (CTE) than the second dielectric layer.

Example 31 includes the subject matter of any one of Examples 22-30, wherein the core layer comprises an organic material.

Example 32 includes the subject matter of any one of Examples 22-30, wherein the core layer comprises glass.

Example 33 includes the subject matter of any one of Examples 22-32, wherein the circuit component is a capacitor or inductor.

Example 34 includes the subject matter of Example 33, wherein the circuit component is a deep trench capacitor.

Example 35 is an integrated circuit package comprising: an integrated circuit package substrate according to any one of Examples 1-34; and an integrated circuit die coupled to the package substrate.

Example 36 is a system comprising: a circuit board; and an integrated circuit package coupled to the circuit board, the integrated circuit package according to Example 35.

Example 37 is a method comprising: placing a circuit component inside a cavity defined by a core layer of a substrate; placing a multi-layer dielectric sheet above the core layer, the multi-layer dielectric sheet comprising a first dielectric layer and a second dielectric layer above the first dielectric layer, the first dielectric layer and second dielectric layer; heating the multi-layer dielectric sheet to cause the first dielectric layer and the second dielectric layer to flow into the cavity; curing the first dielectric layer and the second dielectric layer; and forming buildup layers on the core layer.

Example 38 includes the subject matter of Example 37, wherein the first dielectric layer comprises first filler materials and the second dielectric layer comprises second filler materials.

Example 39 includes the subject matter of Example 38, wherein the first filler materials are different from the second filler materials.

Example 40 includes the subject matter of Example 38 or 39, wherein a density of the first filler materials in the first dielectric layer is different than a density of the second filler materials in the second dielectric layer.

Example 41 includes the subject matter of any one of Examples 38-40, wherein the first filler materials have a different size than the second filler materials.

Example 42 includes the subject matter of any one of Examples 38-41, wherein the first filler materials and the second filler materials comprise one or more of silicate, amorphous silicas, quartz, mica, titanium dioxide, magnesium carbonate, aluminum nitride, alumina, boron nitride, magnesium hydroxide, chalk, limestone, feldspar, barium sulfate, and cobalt iron alloy.

Example 43 includes the subject matter of any one of Examples 24-42, wherein the first dielectric layer has a higher coefficient of thermal expansion (CTE) than the second dielectric layer.

Example 44 includes the subject matter of any one of Examples 24-43, wherein the circuit component is a capacitor or inductor.

Example 45 includes the subject matter of Example 44, wherein the circuit component is a deep trench capacitor.

Example 46 is a method comprising: placing a circuit component inside a cavity defined by a core layer of a substrate; placing polymer material in the cavity; placing a dielectric sheet above the core layer; heating the polymer material and the dielectric sheet; curing the polymer material and the dielectric; and forming buildup layers on the core layer.

Example 47 includes the subject matter of Example 46, wherein placing the polymer material in the cavity comprises one or more of stencil-based screen printing the polymer into the cavity, inkjet printing the polymer into the cavity, and pneumatic plunger dot dispensing the polymer into the cavity.

Example 48 includes the subject matter of Example 46 or 47, wherein the polymer material comprises one or more of an epoxy, a polyimide, a polyacrylate or polyacrylate composites, and a prepreg material.

Example 49 includes the subject matter of any one of Examples 46-48, wherein the polymer material comprises a filler material.

Example 50 includes the subject matter of Example 49, wherein the filler material comprises one or more of silicate, amorphous silicas, quartz, mica, titanium dioxide, magnesium carbonate, aluminum nitride, alumina, boron nitride, magnesium hydroxide, chalk, limestone, feldspar, barium sulfate, and cobalt iron alloy.

Example 51 includes the subject matter of any one of Examples 46-50, wherein the circuit component is a capacitor or inductor.

Example 52 includes the subject matter of Example 51, wherein the circuit component is a deep trench capacitor.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit package substrate comprising:
a core layer defining a cavity;
a circuit component inside the cavity;
a first dielectric layer inside the cavity, the first dielectric layer adjacent the circuit component;
a second dielectric layer inside the cavity and below the first dielectric layer; and
buildup layers on the core layer, the buildup layers comprising a plurality of metallization layers, wherein at least one metallization layer is in connection with the circuit component.

2. The integrated circuit package substrate of claim 1, wherein the first dielectric layer encapsulates the circuit component in the cavity.

3. The integrated circuit package substrate of claim 1, wherein the first dielectric layer comprises first filler materials and the second dielectric layer comprises second filler materials.

4. The integrated circuit package substrate of claim 3, wherein the first filler materials are different from the second filler materials.

5. The integrated circuit package substrate of claim 3, wherein a density of the first filler materials in the first dielectric layer is different than a density of the second filler materials in the second dielectric layer.

6. The integrated circuit package substrate of claim 3, wherein the first filler materials have a different size than the second filler materials.

7. The integrated circuit package substrate of claim 3, wherein the first filler materials and the second filler materials comprise one or more of silicate, amorphous silicas, quartz, mica, titanium dioxide, magnesium carbonate, aluminum nitride, alumina, boron nitride, magnesium hydroxide, chalk, limestone, feldspar, barium sulfate, and cobalt iron alloy.

8. The integrated circuit package substrate of claim 1, wherein the first dielectric layer has a higher coefficient of thermal expansion (CTE) than the second dielectric layer.

9. The integrated circuit package substrate of claim 1, wherein the circuit component is a capacitor or inductor.

10. An integrated circuit package substrate comprising:
a core layer defining a cavity;
a circuit component at least partially inside the cavity;
a polymer material inside the cavity adjacent the circuit component; and
buildup layers on the core layer, the buildup layers comprising a plurality of metallization layers, wherein at least one metallization layer is in connection with the circuit component.

11. The integrated circuit package substrate of claim 10, wherein the polymer material encapsulates the circuit component in the cavity.

12. The integrated circuit package substrate of claim 10, wherein the polymer material comprises one or more of an epoxy, a polyimide, a polyacrylate or polyacrylate composites, and a prepreg material.

13. The integrated circuit package substrate of claim 10, wherein the polymer material comprises a filler material.

14. The integrated circuit package substrate of claim 13, wherein the filler material comprises one or more of silicate, amorphous silicas, quartz, mica, titanium dioxide, magnesium carbonate, aluminum nitride, alumina, boron nitride, magnesium hydroxide, chalk, limestone, feldspar, barium sulfate, and cobalt iron alloy.

15. The integrated circuit package substrate of claim 10, wherein the circuit component is a capacitor or inductor.

16. An integrated circuit package substrate comprising:
a core layer;
first buildup layers on a first side of the core layer, the first buildup layers comprising a plurality of metallization layers;
second buildup layers on a second side of the core layer, the second buildup layers comprising a plurality of metallization layers;
a circuit component in an opening in the core layer between the first buildup layers and the second buildup layers;
a first dielectric layer and a second dielectric layer in the opening in the core layer between the first buildup layers and the second buildup layers, the first dielectric layer adjacent the circuit component.

17. The integrated circuit package substrate of claim 16, wherein the first dielectric layer is a polymer material.

18. The integrated circuit package substrate of claim 16, wherein the first dielectric layer encapsulates the circuit component in the opening.

19. The integrated circuit package substrate of claim 16, wherein the first dielectric layer comprises first filler materials and the second dielectric layer comprises second filler materials.

20. The integrated circuit package substrate of claim 19, wherein the first filler materials are different from the second filler materials.
